(19) United States
(12) Patent Application Publication
(10) Pub. No.: US 2026/0011661 A1
(43) Pub. Date: Jan. 8, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Wen-Jung TSAI, Taichung City (TW); Chih-Hsien CHIU, Taichung City (TW); Chien-Cheng LIN, Taichung City (TW); Chia-Chen CHIAO, Taichung City (TW); Chun-Sheng CHANG, Taichung City (TW)

(73) Assignee: SILICONWARE PRECISION INDUSTRIES CO., LTD., Taichung City (TW)

(21) Appl. No.: 18/982,357

(22) Filed: Dec. 16, 2024

(30) Foreign Application Priority Data
Jul. 8, 2024 (TW) 113125530

(51) Int. Cl. H01L 23/60; H01L 21/78; H01L 23/00; H01L 23/31; H01L 23/498; H01L 25/07

(52) U.S. Cl. CPC H01L 23/60; H01L 21/78; H01L 23/3171; H01L 23/49816; H01L 23/49844; H01L 24/05; H01L 24/13; H01L 25/072; H01L 2224/05569; H01L 2224/13023; H01L 2924/3025

(57) ABSTRACT

An electronic package and a manufacturing method thereof are provided. The electronic package includes an electronic component and a shielding layer. The electronic component has an active surface, an inactive surface opposite to the active surface, and a side surface connecting the active surface and the active surface. The shielding layer is disposed on the electronic component and directly contacts and completely covers the inactive surface and the side surface. The shielding layer is formed directly on the surface of the electronic component, thereby shielding electromagnetic interference, reducing the size of the electronic package, and lowering production costs.

### BACKGROUND

### 1. Technical Field

The present disclosure relates to a packaging structure, and more particularly, to an electronic package and a manufacturing method thereof.

### 2. Description of Related Art

As semiconductor technology advances, many semiconductor products, especially system in package (SiP) products, have shielding functions to prevent electromagnetic interference (EMI), thereby enhancing electrical quality.

As shown in FIG. 1, a conventional semiconductor package 1 is provided with a plurality of semiconductor chips 11 disposed on a package substrate 10, an encapsulant 13 covering each of the semiconductor chips 11, and a shielding layer 14 of a metal material formed on an upper surface of the encapsulant 13 and a side surface of the package substrate 10 to protect each of the semiconductor chips 11 from external electromagnetic interference. In addition, a shielding wall 12 of a metal material may be provided around the plurality of semiconductor chips 11 to prevent electromagnetic waves or signal interference between the plurality of semiconductor chips 11.

As electronic products are designed for miniaturization, especially System in a Package (SiP) products, an area of a surface 10a of the package substrate 10 also needs to be reduced accordingly. However, the surface 10a of the package substrate 10 needs to be provided with a shielding wall 12. The shielding wall 12 not only occupies the local area of the surface 10a of the package substrate 10, making it impossible to reduce the size of the package substrate 10 any further, but also occupies the wiring area of the surface 10a of the package substrate 10, thereby constraining the wiring of the package substrate 10 and precluding further enhancement of the product's functionality.

Therefore, how to avoid the deficiencies of the prior art has become an urgent issue to be solved.

### SUMMARY

In view of the various deficiencies of the prior art, the present disclosure provides an electronic package comprising an electronic component, a shielding layer, and a redistribution layer. The electronic component has an active surface, an inactive surface opposite to the active surface, and a side surface connecting the active surface and the inactive surface. The shielding layer is disposed on the electronic component and directly contacts and completely covers the inactive surface and the side surface. The redistribution layer is formed on the active surface of the electronic component and is electrically connected to the electronic component and the shielding layer.

The present disclosure also provides a method for manufacturing an electronic package comprising: forming a redistribution layer on a semiconductor structure; cutting the semiconductor structure to separate an electronic component, wherein the electronic component has an active surface, an inactive surface opposite to the active surface, and a side surface connecting the active surface and the inactive surface, and wherein the redistribution layer is formed on the active surface of the electronic component and is electrically connected to the electronic component; and forming a shielding layer on the electronic component and thus the shielding layer directly contacting and completely covering the inactive surface and the side surface and electrically connected to the redistribution layer.

In the present disclosure, the shielding layer is formed directly on the surface of the electronic component, thereby shielding electromagnetic interference, reducing the size of the electronic package, and lowering production costs.

### BRIEF DESCRIPTION OF THE DRAWINGS

FIG. 1 is a schematic cross-sectional view illustrating a conventional semiconductor package.

FIG. 2A to FIG. 2E are schematic cross-sectional side views illustrating a manufacturing method of an electronic package according to a first embodiment of the present disclosure.

FIG. 2F is a cross-sectional top view illustrating a manufacturing method of an electronic package according to a first embodiment of the present disclosure.

FIG. 3A to FIG. 3D are schematic cross-sectional side views illustrating a manufacturing method of an electronic package according to a second embodiment the present disclosure.

FIG. 4A to FIG. 4E are schematic cross-sectional side views illustrating a manufacturing method of an electronic package according to a third embodiment the present disclosure.

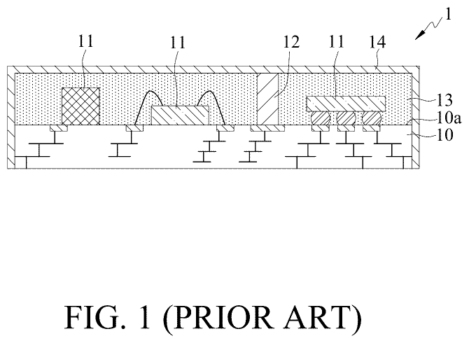

### DETAILED DESCRIPTIONS

The following describes the implementation of the present disclosure with examples. Those skilled in the art can easily understand other advantages and effects of the present disclosure from the contents disclosed in this specification.

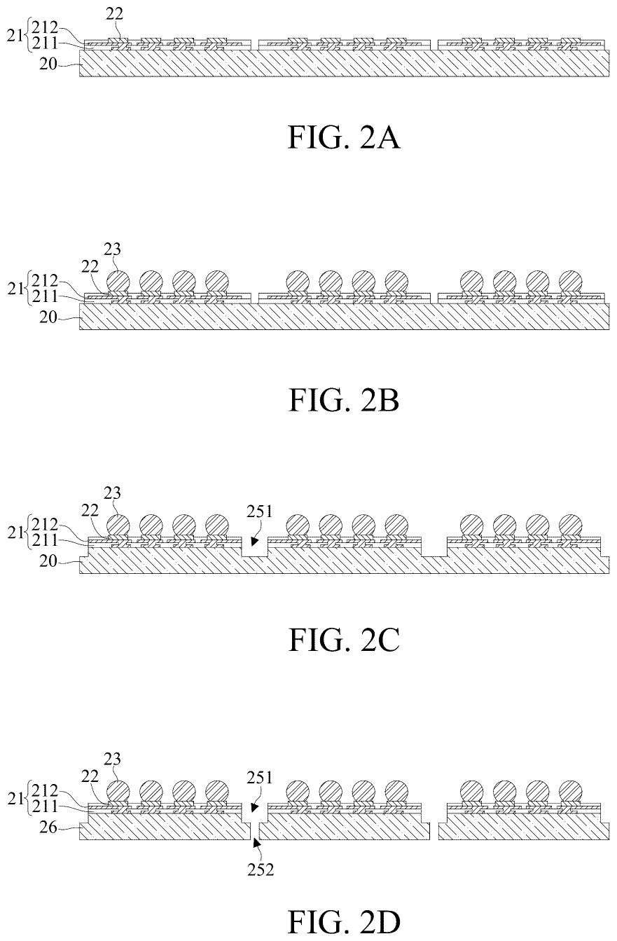

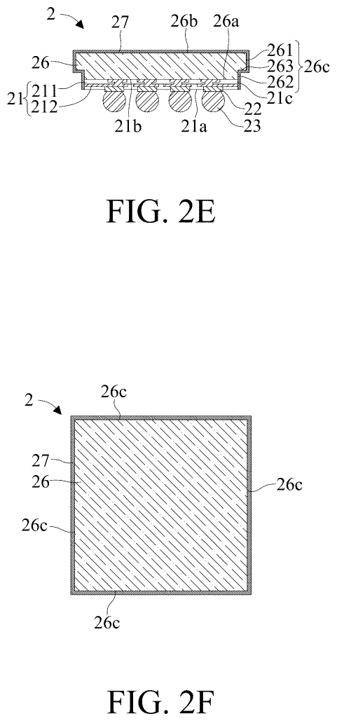

FIG. 2A to FIG. 2E are schematic cross-sectional side views illustrating a manufacturing method of an electronic package 2 according to a first embodiment of the present disclosure. FIG. 2F is a cross-sectional top view illustrating a manufacturing method of an electronic package 2 according to a first embodiment of the present disclosure.

First, as shown in FIG. 2A, a redistribution layer 21 is formed on a semiconductor structure 20, and a metal layer 22 is formed on the redistribution layer 21.

The semiconductor structure 20 may be a wafer or other structure for an electronic component to be disposed thereon. The electronic component may be an integrated circuit and a transistor, a resistor, a capacitor, or an inductor therein.

The redistribution layer 21 includes at least one insulating layer 211 and at least one circuit layer 212 bonding to the at least one insulating layer 211. For example, the circuit layer 212 may be formed of copper or other conductive materials, and the insulating layer 211 may be formed of polybenzoxazole (PBO), polyimide (PI), prepreg (PP), or other dielectric materials.

The metal layer 22 may be an under bump metallurgy (UBM), which is made of conductive metal.

As shown in FIG. 2B, a plurality of conductors 23 are formed on the metal layer 22. Each of the conductors 23 is, for example, a conductive pillar, a conductive bump, a solder ball, or other conductive structure.

As shown in FIG. 2C, the semiconductor structure 20 is cut. The cutting cuts through the redistribution layer 21 (but not through the semiconductor structure 20) to form a first groove 251 on the semiconductor structure 20. In addition, the cutting cuts off a part of the redistribution layer 21 to expose the circuit layer 212 within the redistribution layer 21.

Next, as shown in FIG. 2D, the cutting is performed in the first groove 251 to form a second groove 252, the semiconductor structure 20 is thus cut through, thereby separating the semiconductor structure 20 into a plurality of electronic components 26. A width of the second groove 252 is smaller than that of the first groove 251. Each of the electronic components 26 may be a semiconductor chip, an integrated circuit, a transistor, a resistor, a capacitor, or an inductor.

As shown in FIG. 2E, a shielding layer 27 is formed on each of the electronic components 26 to complete the electronic package 2. For example, the shielding layer 27 may be formed by sputter coating. The shielding layer 27 can be a copper layer or other conductive metal layer to provide electromagnetic shielding for the electronic component 26.

FIG. 2E only shows one electronic package 2 as an example. In fact, each of the electronic components 26 cut in FIG. 2D as well as the redistribution layer 21, metal layer 22, conductors 23 and other structures thereon form an electronic package 2 shown in FIG. 2E.

In the electronic package 2, the conductors 23 are electrically connected to the electronic component 26 via the metal layer 22 and the circuit layer 212 in the redistribution layer 21.

The electronic component 26 has an active surface 26a and an inactive surface 26b opposite to the active surface 26a, and a side surface 26c connecting the active surface 26a and the inactive surface 26b. The redistribution layer 21 is formed on the active surface 26a of the electronic component 26. The shielding layer 27 directly contacts and completely covers the inactive surface 26b and the side surface 26c of the electronic component 26.

In addition, the side surface 26c of the electronic component 26 includes a first side surface 261, a second side surface 262, and a transition surface 263 connecting the first side surface 261 and the second side surface 262. The first side surface 261 is parallel to the second side surface 262, and the transition surface 263 is parallel to neither the first side surface 261 nor the second side surface 262. The second side surface 262 is retracted relative to the first side surface 261, and the retraction is caused by the width difference between the first groove 251 and the second groove 252 during cutting. Therefore, the distance by which the second side surface 262 is retracted is equal to half of the width difference between the first groove 251 and the second groove 252.

The redistribution layer 21 has a first surface 21a, a second surface 21b opposite to the first surface 21a, and a lateral surface 21c connecting the first surface 21a and the second surface 21b. The second surface 21b of the redistribution layer 21 directly contacts the active surface 26a of the electronic component 26. The metal layer 22 is formed on the first surface 21a of the redistribution layer 21. In addition, the lateral surface 21c of the redistribution layer 21 is aligned with the second side surface 262 of the electronic component 26.

Furthermore, as shown in FIG. 2E, the shielding layer 27 extends downward beyond the second side surface 262 of the electronic component 26 to directly contact and completely cover the lateral surface 21c of the redistribution layer 21. Therefore, the circuit layer 212 exposed from the redistribution layer 21 is electrically connected to the shielding layer 27.

The shielding layer 27 shown in FIG. 2E covers both left and right sides of the side surface 26c of the electronic component 26 and the lateral surface 21c of the redistribution layer 21. In one embodiment, the electronic component 26 is quadrilateral in shape, such as a square or a rectangle. The shielding layer 27 completely covers the side surfaces 26c of the electronic component 26 on all four sides (e.g., top, bottom, left and right sides in FIG. 2F) from a top view.

Similarly, the redistribution layer 21 is also quadrilateral in shape, such as a square or a rectangle, and the shielding layer 27 also completely covers the lateral surfaces 21c of the redistribution layer 21 on all four sides.

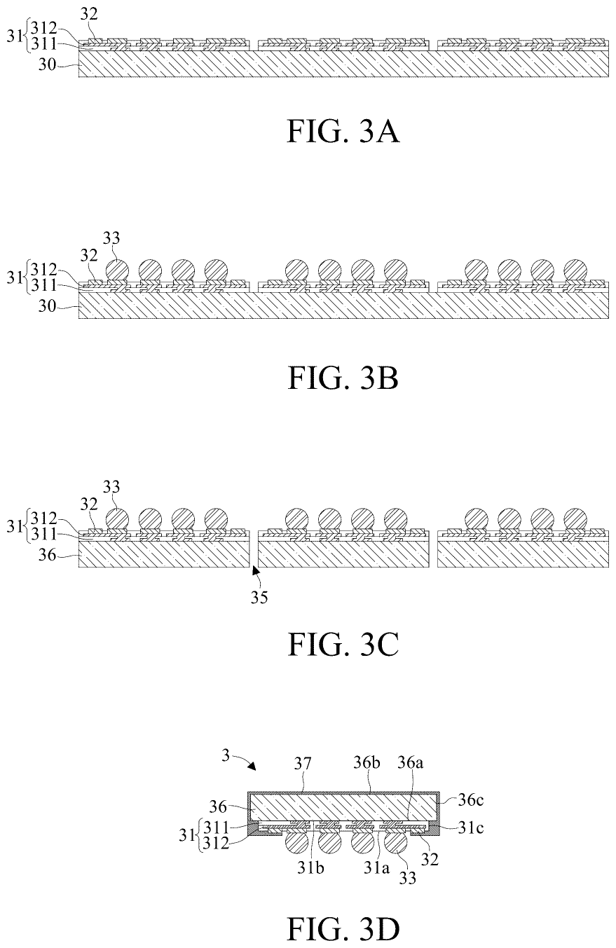

FIG. 3A to FIG. 3D are schematic cross-sectional side views illustrating a manufacturing method of an electronic package 3 according to a second embodiment the present disclosure. The second embodiment is identical or similar to the aforementioned first embodiment in many places. Consequently, the differences between the two embodiments are highlighted below, and details of other identical or similar parts are omitted or only briefly explained herein.

First, as shown in FIG. 3A, a redistribution layer 31 is formed on a semiconductor structure 30, and a metal layer 32 is formed on the redistribution layer 31.

The redistribution layer 31 includes at least one insulating layer 311 and at least one circuit layer 312 bonding to the at least one insulating layer 311. The metal layer 32 may be an under bump metallurgy (UBM) or a copper layer.

As shown in FIG. 3B, a plurality of conductors 33 are formed on the metal layer 32.

As shown in FIG. 3C, the semiconductor structure 30 is cut. The cutting cuts through the redistribution layer 31 to form a groove 35 in the semiconductor structure 30. The groove 35 cuts through the semiconductor structure 30 to separate the semiconductor structure 30 into a plurality of electronic components 36.

As shown in FIG. 3D, a shielding layer 37 is formed on each of the electronic components 36 to finish the electronic package 3.

In the electronic package 3, the conductors 33 are electrically connected to the electronic component 36 via the metal layer 32 and the circuit layer 312 in the redistribution layer 31.

The electronic component 36 has an active surface 36a and an inactive surface 36b opposite to the active surface 36a, and a side surface 36c connecting the active surface 36a and the inactive surface 36b. The redistribution layer 31 is formed on the active surface 36a of the electronic component 36. The shielding layer 37 directly contacts and completely covers the inactive surface 36b and the side surface 36c of the electronic component 36.

The redistribution layer 31 has a first surface 31a, a second surface 31b opposite to the first surface 31a, and a lateral surface 31c connecting the first surface 31a and the second surface 31b. The second surface 31b of the redistribution layer 31 directly contacts the active surface 36a of the electronic component 36. The metal layer 32 is formed on the first surface 31a of the redistribution layer 31.

As shown in FIG. 3D, the shielding layer 37 extends downward and exceeds the side surface 36c of the electronic component 36 to directly contact and completely cover the lateral surface 31c of the redistribution layer 31. In addition, the shielding layer 37 may further directly contact and partially cover the first surface 31a of the redistribution layer 31. In one embodiment, the circuit layer 312 of the redistribution layer 31 is not exposed, so that the shielding layer 37 is electrically connected to the metal layer 32 instead of the circuit layer 312 of the redistribution layer 31. In detail, a part of the metal layer 32 is electrically connected to the shielding layer 37, and another part of the metal layer 32 is electrically connected to the conductors 33.

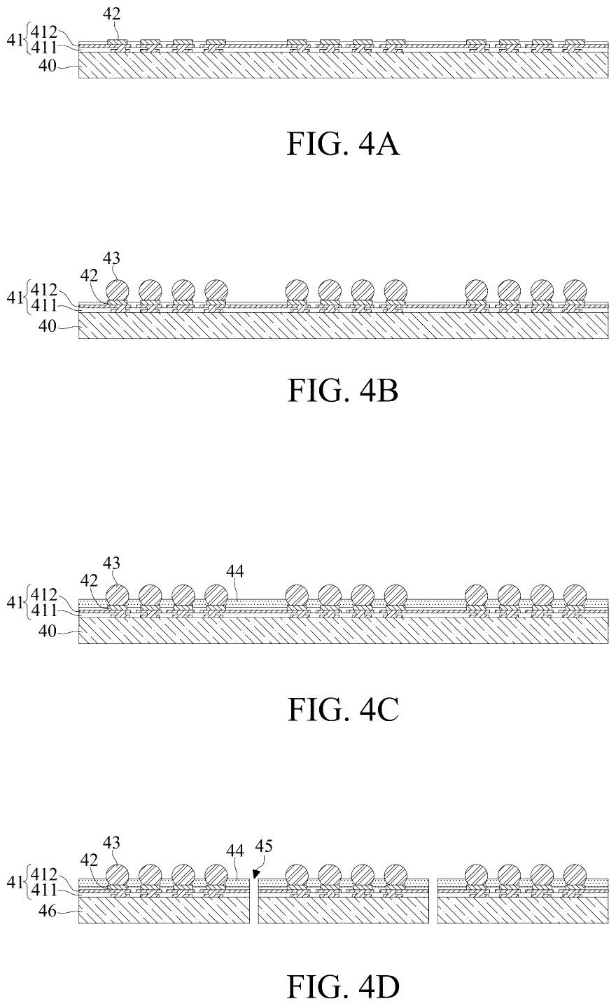

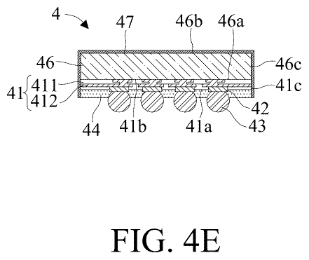

FIG. 4A to FIG. 4E are schematic cross-sectional side views illustrating a manufacturing method of an electronic package 4 according to a third embodiment the present disclosure. The third embodiment is identical or similar to the aforementioned first and second embodiments in many places. Consequently, the differences between the two embodiments are highlighted below, and the details of other identical or similar parts are omitted or only briefly explained herein.

First, as shown in FIG. 4A, a redistribution layer 41 is formed on a semiconductor structure 40, and then a metal layer 42 is formed on the redistribution layer 41.

The redistribution layer 41 includes at least one insulating layer 411 and at least one circuit layer 412 bonding to the at least one insulating layer 411. The metal layer 42 may be an under bump metallurgy (UBM).

As shown in FIG. 4B, a plurality of conductors 43 are formed on the metal layer 42.

As shown in FIG. 4C, an encapsulating layer 44 is formed on the redistribution layer 41, wherein the encapsulating layer 44 partially convers the conductors 43. The encapsulating layer 44 is made of an insulating layer, such as polyimide (PI), epoxy resin encapsulants or encapsulating material. In addition, the encapsulating layer 44 may be formed by molding, lamination or coating.

As shown in FIG. 4D, the semiconductor structure 40 along with the redistribution layer 41 and encapsulating layer 44 thereon are cut. A groove 45 formed by the cutting cuts through the encapsulating layer 44, the redistribution layer 41 and the semiconductor structure 40, the circuit layer 412 of the redistribution layer 41 is thus exposed, and a plurality of electronic components 46 are separated from the semiconductor structure 40.

As shown in FIG. 4E, a shielding layer 47 is formed on each of the electronic components 46 to finish the electronic package 4.

In the electronic package 4, the conductors 43 are electrically connected to the electronic component 46 via the metal layer 42 and the circuit layer 412 in the redistribution layer 41.

The electronic component 46 has an active surface 46a and an inactive surface 46b opposite to the active surface 46a, and a side surface 46c connecting the active surface 46a and the inactive surface 46b. The redistribution layer 41 is formed on the active surface 46a of the electronic component 46. The shielding layer 47 directly contacts and completely covers the inactive surface 46b and the side surface 46c of the electronic component 46.

The redistribution layer 41 has a first surface 41a, a second surface 41b opposite to the first surface 41a, and a lateral surface 41c connecting the first surface 41a and the second surface 41b. The second surface 41b of the redistribution layer 41 directly contacts the active surface 46a of the electronic component 46. The metal layer 42 and the encapsulating layer 44 are formed on the first surface 41a of the redistribution layer 41.

As shown in FIG. 4E, the shielding layer 47 extends downward and exceeds the side surface 46c of the electronic component 46 to directly contact and completely cover the lateral surface 41c of the redistribution layer 41, and further extends downward to directly contact and partially cover the encapsulating layer 44. In addition, the shielding layer 47 is electrically connected to the circuit layer 412 of the redistribution layer 41.

As in the first embodiment shown in FIG. 2F, the electronic component 46 in this embodiment shown is quadrilateral in shape such as a square or a rectangle, and the shielding layer 47 completely covers the side surfaces 46c of the electronic component 46 on all four sides. The redistribution layer 41 and the encapsulating layer 44 are in the same quadrilateral shape, and the shielding layer 47 also completely covers the redistribution layer 41 and the encapsulating layer 44 on four sides. In addition, the shielding layer 47 completely covers the inactive surface 46b of the electronic component 46, and the encapsulating layer 44 completely covers the rest areas of the first surface 41a of the redistribution layer 41 except for the area where the metal layer 42 and the conductors 43 are located. Therefore, the shielding layer 47 and the encapsulating layer 44 form a six-sided protection of the electronic package 4.

The electronic package and manufacturing method thereof according to embodiments of the present disclosure involves the direct formation of a shielding layer on the surface of the electronic component. The shielding layer is capable of shielding electromagnetic interference (EMI) to prevent electromagnetic interference between the external environment and the electronic component. There is no intermediate structure such as an encapsulant between the shielding layer and the electronic component. Moreover, the shielding layer adapts to the miniaturization of the electronic component, avoiding the problems of conventional semiconductor package and reducing the size of the package. Additionally, the electronic package of the present disclosure can be produced using existing semiconductor packaging processes, obviating the necessity for the development of a special process or the purchase of special equipment, thereby reducing production costs.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
an electronic component having an active surface, an inactive surface opposite to the active surface, and a side surface connecting the active surface and the inactive surface;
a shielding layer disposed on the electronic component and directly contacting and completely covering the inactive surface and the side surface; and
a redistribution layer formed on the active surface of the electronic component and electrically connected to the electronic component and the shielding layer.

2. The electronic package of claim 1, wherein the side surface includes a first side surface, a second side surface, and a transition surface connecting the first side surface and the second side surface, the first side surface is parallel to the second side surface, and the transition surface is parallel to neither the first side surface nor the second side surface.

3. The electronic package of claim 2, wherein the second side surface is retracted relative to the first side surface.

4. The electronic package of claim 2, wherein the redistribution layer has a lateral surface aligned with the second side surface of the electronic component.

5. The electronic package of claim 4, wherein the redistribution layer includes an insulating layer and a circuit layer bonding to the insulating layer, and the circuit layer is electrically connected to the electronic component and the shielding layer.

6. The electronic package of claim 1, wherein the redistribution layer has a first surface, a second surface opposite to the first surface, and a lateral surface connecting the first surface and the second surface.

7. The electronic package of claim 6, wherein the shielding layer directly contacts and completely covers the lateral surface of the redistribution layer.

8. The electronic package of claim 7, wherein the shielding layer directly contacts and partially covers the first surface of the redistribution layer.

9. The electronic package of claim 6, further comprising:
a metal layer disposed on the first surface of the redistribution layer; and
a conductor disposed on the metal layer and electrically connected to the electronic component via the metal layer and the redistribution layer.

10. The electronic package of claim 9, wherein a part of the metal layer is electrically connected to the shielding layer, and another part of the metal layer is electrically connected to the conductor.

11. The electronic package of claim 9, further comprising:
an encapsulating layer disposed on the first surface of the redistribution layer and partially covering the conductor.

12. The electronic package of claim 11, wherein the shielding layer partially covers the encapsulating layer.

13. A method for manufacturing an electronic package, comprising:
forming a redistribution layer on a semiconductor structure;
cutting the semiconductor structure to separate an electronic component, wherein the electronic component has an active surface, an inactive surface opposite to the active surface, and a side surface connecting the active surface and the inactive surface, and wherein the redistribution layer is formed on the active surface of the electronic component and is electrically connected to the electronic component; and
forming a shielding layer on the electronic component and thus the shielding layer directly contacting and completely covering the inactive surface and the side surface and electrically connected to the redistribution layer.

14. The method of claim 13, wherein the side surface includes a first side surface, a second side surface, and a transition surface connecting the first side surface and the second side surface, wherein the first side surface is parallel to the second side surface, and the transition surface is parallel to neither the first side surface nor the second side surface.

15. The method of claim 14, wherein the second side surface is retracted relative to the first side surface.

16. The method of claim 14, wherein the redistribution layer has a lateral surface aligned with the second side surface of the electronic component.

17. The method of claim 16, wherein the redistribution layer includes an insulating layer and a circuit layer bonding to the insulating layer, and the circuit layer is electrically connected to the electronic component and the shielding layer.

18. The method of claim 13, wherein the redistribution layer has a first surface, a second surface opposite to the first surface, and a lateral surface connecting the first surface and the second surface.

19. The method of claim 18, wherein the shielding layer directly contacts and completely covers the lateral surface of the redistribution layer.

20. The method of claim 19, wherein the shielding layer directly contacts and partially covers the first surface of the redistribution layer.

21. The method of claim 18, wherein prior to cutting the semiconductor structure to separate an electronic component, the method further comprises:
forming a metal layer on the first surface of the redistribution layer; and
forming a conductor on the metal layer, wherein the conductor is electrically connected to the electronic component via the metal layer and the redistribution layer.

22. The method of claim 21, wherein a part of the metal layer is electrically connected to the shielding layer, and another part of the metal layer is electrically connected to the conductor.

23. The method of claim 21, wherein prior to cutting the semiconductor structure to separate an electronic component, the method further comprises:
forming an encapsulating layer on the first surface of the redistribution layer, wherein the encapsulating layer partially covers the conductor.

24. The method of claim 23, wherein the shielding layer partially covers the encapsulating layer.

25. The method of claim 18, wherein the cutting cuts off a part of the redistribution layer to expose a circuit layer within the redistribution layer, and thus the circuit layer is electrically connected to the shielding layer.

26. The method of claim 18, wherein the cutting firstly cuts through the redistribution layer to form a first groove on the semiconductor structure, and cuts in the first groove to form a second groove, so as to cut through the semiconductor structure for separating the electronic component.

27. The method of claim 26, wherein a width of the second groove is smaller than a width of the first groove.
